(19) United States
(12) Patent Application Publication
(10) Pub. No.: US 2013/0057952 A1
(43) Pub. Date: Mar. 7, 2013

(54) SUBSTRATE MADE OF AN ALUMINUM-SILICON ALLOY OR CRYSTALLINE SILICON, METAL MIRROR, METHOD FOR THE PRODUCTION THEREOF, AND USE THEREOF

(71) Applicants: Stefan Risse, Jena (DE); Andreas Gebhardt, Apolda (DE); Thomas Peschel, Jena (DE); Wieland Stockl, Jena (DE)

(72) Inventors: Stefan Risse, Jena (DE); Andreas Gebhardt, Apolda (DE); Thomas Peschel, Jena (DE); Wieland Stockl, Jena (DE)

(73) Assignee: FRAUNHOFER-GESELLSCHAFT ZUR FORDERUNG DER ANGEWANDTEN FORSCHUNG E.V., Munchen (DE)

(21) Appl. No.: 13/394,507

(22) PCT Filed: Sep. 9, 2010
(86) PCT No.: PCT/EP10/05556

§ 371 Date: May 11, 2012

(30) Foreign Application Priority Data
Sep. 9, 2009 (DE) 10 2009 040 785.5

(51) Int. Cl. G02B 5/08; B32B 15/04; C23C 14/30; C23C 14/35; B05D 5/06; B32B 9/04; C23C 14/14

(52) U.S. Cl. 359/360; 359/884; 359/359; 428/446; 428/450; 428/336; 204/192.27; 427/162; 427/597

(57) ABSTRACT

The invention relates to a substrate made of an aluminium-silicon alloy or crystalline silicon to which a polishable layer is applied and also to a metal mirror which comprises this substrate. Furthermore, the invention relates to a method for the production of metal mirrors and also the use of the metal mirror according to the invention.

The invention relates to a substrate made of an aluminium-silicon alloy or crystalline silicon to which a polishable layer is applied and also to a metal mirror which comprises this substrate. Furthermore, the invention relates to a method for the production of metal mirrors and also the use of the metal mirror according to the invention.

At present there is increasing demand for ultraprecise production of complex lens surfaces (free shapes, aspherical shapes) with high demands on the component surfaces (shape and roughness) and on the permissible temperature range. Potential applications thereby reside in the fields of laser technology, defence technology, space and lithography.

Ultraprecision machining (diamond turning and milling) offers the possibility of producing metal lens systems with complex surface shapes. Turning machining of spherical and aspherical surfaces with shape deviations <200 nm with a component diameter of 100 mm and roughnesses of RMS=2 . . . 5 nm for suitable materials, such as aluminium, copper or nickel, is state of the art. Whilst the requirements for IR applications are hence fulfilled with respect to shape deviation, the roughness and trueness to shape which can be achieved by this machining process is inadequate for short wavelengths. Hence a subsequent fine polishing or correction polishing is necessary. This process is implemented preferably with aluminium substrates which are provided with an amorphous nickel-phosphorus layer (NiP). The disadvantage of this material pairing is the considerable difference in thermal expansion of aluminium (23.8 ppm/K) and an NiP layer (12 ppm/K). If the lens parts undergo a temperature change during use, stresses and deformations are produced by means of the resulting bimetal effect, which stresses and deformations can significantly influence the optical effect or, in many cases, make the described technology impossible.

By using an expansion-matched alloy (AlSi₄₀, AlSi₄₂) with almost the same coefficients of expansion (12.5 ppm/K or 12.8 ppm/K) as NiP, this disadvantage can be eliminated. A further advantage of the material pairing resides in the lower density and higher modulus of elasticity of the Al—Si alloy, which accommodates both lightweight applications and improved shape precision (DE 102 005 026 418). In the case of the finish machining in an NiP layer, renewed machining by diamond turning is necessary and possible in the thick layer. In addition to the increased manufacturing complexity, a minimum thickness of the layer is hence unavoidable. In general, the shape correction of the lens surface is more successful using diamond turning in soft metals, such as aluminium 6061 or other aluminium alloys, than in hard chemical nickel layers. One disadvantage of chemical NiP as polished layer resides in the instability of the amorphous structure at increased temperatures. The thermally-induced beginning recrystallisation of the NiP alloy at temperatures above 220° C. leads to dramatic roughening of the surface (orange peel effect) and the build up of mechanical stresses which do not permit use in the high-temperature range.

In addition to metal substrates for high-end mirrors, approaches for a solution exist based on the use of silicon carbide as mirror carrier. Without doubt, this ceramic material has excellent mechanical properties and high-quality lens surfaces can be produced, however the technological complexity for producing the mirror shapes, in particular however also production of housing, frames and entire instrument with respect to technical apparatus, is hugely complex. A flexible CNC machining is not possible.

In comparison to the above-mentioned AlSiₓₓ/NiP system, the stability is significantly better as a result of the higher ratio of heat conductivity to thermal expansion and, on the other hand, relative to thermal gradients, in particular due to absorbed radiation (“thermal lens”).

Starting herefrom, it is the object of the present invention to produce a stable, polishable or polished layer on a substrate with lower complexity with respect to technical apparatus, the materials used having comparable coefficients of expansion.

This object is achieved by the substrate having the features of claim 1. Claim 7 relates to a metal mirror, claim 13 to a method for the production of the metal mirror and claim 16 to the use thereof. Further advantageous embodiments are contained in the dependent claims.

According to the invention, the substrate consists of an aluminium-silicon alloy or crystalline silicon to which a polishable layer is applied, which layer consists of amorphous silicon, microcrystalline silicon, silicon carbide, silicon nitride, titanium nitride, aluminium oxide, zirconium oxide, chromium and/or mixtures hereof. The AlSiₓₓ alloy can thereby be modified (e.g. 42% Si; 50% Si; 60% Si). Specific properties are achieved or are changed specifically with the stoichiometric composition (modulus of elasticity; mass; coefficient of expansion).

It is the idea of the invention to produce the substrate from an aluminium-silicon alloy by means of ultraprecise diamond machining, to provide this with a polishable silicon layer and, by means of a polishing method (CMP: chemical mechanical polishing, IBF: ion beam finishing or ion beam polishing), to produce the quality of the reflecting surface by the machining of the silicon layer. Finally, coating with an optical functional layer (reflection layer) can be effected.

The substrate (or mirror bulk material) consists of a machinable aluminium-silicon alloy. Hence a CNC milling/boring/turning machining is possible with high flexibility. The surface which ultimately serves as optically active surface is produced by diamond machining.

An intermediate layer which acts as adhesive- or as barrier layer can be disposed between the substrate and the polishable layer. A precondition for the coating is correspondingly good cleaning of the surface to be coated, e.g. the substrate surface. Hence it is possible to obtain both good layer adhesion and layer quality.

The polishable layer can thereby have a thickness of 1 μm to 10 μm, preferably of 3 μm to 6 μm. The thickness of the intermediate layer which comprises possibly a plurality of layers is preferably between 20 and 200 nm, preferably 100 nm.

Preferably, the intermediate layer consists of metal oxide, in particular aluminium oxide or zirconium oxide, metal, in particular titanium or chromium or comprises these. These materials can also effect good matching, e.g. of the coefficients of expansion of the different materials, which furthermore contributes to increasing the long-term stability of the coated substrate.

In a further variant of the substrate according to the invention, the silicon content of the aluminium-silicon alloy is between 25 and 90% by weight, preferably between 40 and 80% by weight, relative to the total mass of the aluminium-silicon alloy.

From a powder-metallurgy point of view, aluminium-silicon alloys with silicon components up to 87% are possible at present. Hence extensive CTE matching, i.e. matching of the coefficient of expansion, of substrate and polishable layer can be achieved. At the same time, a significant increase in heat conductivity, in the specific rigidity and temperature stability (ratio of conductivity to expansion) is associated with an increasing silicon content.

According to the invention, the metal mirror comprises a substrate as described already, the polishable layer being polished to optical quality.

After coating the substrate with e.g. silicon, smoothing of the surface structures is effected. Silicon represents a well known material with respect to its polishing properties. Extensive knowledge exists from the field of wafer polishing but also from the production of infrared lens systems and mirrors. For applications in the extreme shortwave spectral range (EUV collector mirrors), superpolishes of silicon of a few Angstrom RMS are known. Suitable smoothing methods are for example standard, chemical-mechanical polishing methods and also magnetorheological polishing techniques. Likewise CMP (chemical-mechanical polishing), MRF (magnetorheological finishing) but also ion beam methods are used likewise for shape corrections. Good homogeneity and purity of the layer leads to a constant removal function and hence to a converging shape correction.

Furthermore, the metal mirror can have at least one coating layer on the surface of the polished layer orientated away from the substrate. Preferably, at least one coating layer is a metallic layer, in particular selected from the group consisting of gold, aluminium, silver, silicon-molybdenum and mixtures hereof. At least one coating layer can be a dielectric layer or a metal-dielectric layer.

The coating layer can consist of various materials, according to the wavelength range. A typical layer for the infrared spectral range is gold. Aluminium and silver or dielectric layer stacks can be used for the visible spectral range. In particular for extremely short wavelengths (13 nm), silicon represents the substrate for Si/Mo layer stacks which represent the only alternative for reflections >68% in this spectral range. EUV stands for wavelengths in the extreme ultraviolet range, i.e. 13 to 13.5 nm. By means of a multilayer construction of silicon-molybdenum-silicon-molybdenum in an alternating sequence, the reflection can be raised to approx. 68% in the case of more than 50 and less than 200 double layers. For example mirrors or collector mirrors in the region of the source can be mentioned as applications in this respect.

Furthermore, in the case of the metal mirror, a further layer, in particular a protective layer, can be disposed on the coating layer. This has particularly good scratch resistance and represents protection from environmental influences, e.g. oxidation or moisture.

Typical coating layers such as gold for the IR range or silver for multispectral applications can be provided with a protective layer. Furthermore, also adhesive layers or diffusion barrier layers are possible.

The materials for the protective layer are selected preferably from the group of metal oxides.

According to the invention, a method for the production of metal mirrors is also included, the intermediate layer, the polished layer, the coating layer and/or the protective layer being applied by means of chemical vapour deposition, atomic layer deposition, electron beam evaporation and/or sputtering processes. Furthermore, also magnetron sputtering can be used.

Aluminium-silicon alloys which are used as substrate according to the invention can be machined with conventional hard metal tools, PKD tools and with precise diamond tools. With an increasing silicon component, the materials become more brittle, the influence of the silicon increases. Good machining results are achieved if, in comparison to machining of aluminium alloys, smaller cutting depths and smaller feeds are used. Taking into account the machining instructions given by the material producer, in principle, there are no essential restrictions on the producible shapes. Merely a minimum wall thickness (approx. 0.6 mm) should be taken into account.

According to conventional machining (premanufacture) with an overmeasure of typically one millimetre, tempering of the material is effected in order to reduce any introduced stresses. Good results could be achieved with treatments at 350° C. for a duration of six hours. Subsequently, machining is effected likewise with conventional machine technology. The subsequent mechanical machining is effected with a shape precision <1 μm P-V (peak to valley) and also roughness values of approx. 5 nm to 40 nm RMS (route mean square) by diamond machining. The resulting surfaces show the texture structure (Al- and Si crystallites) microscopically. The machining parameters are identical to those in the machining of conventional aluminium alloys (Al6061, AlSi0.5). The machining of extended mirror surfaces >(100 mm)² is possible without any problems within the tool lifespan. The possibility of machining the substrate material with a specific blade is an essential advantage relative to hard, brittle-elastic materials, such as e.g. silicon carbide.

During deposition of the polishable layer, the coating temperature can increase to up to 150° C. This layer deposition is normally effected in a pressure range of 8·10⁻⁴ mbar to 5·10⁻³ mbar.

The sputtering gas is thereby preferably selected from the group consisting of argon, oxygen, xenon and mixtures hereof. If oxides are deposited, preferably argon and oxygen are used as sputtering gas. The basic pressure which should be below 5·10⁻⁷ mbar is crucial for the quality of the deposited layers.

If adhesive or barrier layers are deposited which have a layer thickness of below 100 nm, the coating temperature does not increase above 40° C. By means of adhesion or barrier layers, for example also interdiffusion can be avoided.

Provided that the polishable layer is applied by magnetron sputtering, a high layer adhesion, low stresses and a pore-free and homogeneous layer are produced by the high-energy coating method. Dependent upon the method, the layer grows in an amorphous or microcrystalline manner. This is a favourable precondition for achieving low roughnesses <2 nm RMS by means of the layer polishing.

A further advantage of the production of the polishable layer by sputtering exists in the high purity of the layer. Typically, highly-pure silicon (99.XX %) is used as target. The thickness of the deposited layer is adjusted normally such that the typical surface structure of the diamond turning (turned grooves) and also surface defects can be polished out with certainty.

In a variant of the method for the production of metal mirrors, the silicon content of the aluminium-silicon alloy and also the thickness and the materials of the polished layer can be chosen such that deformations due to temperature change are extensively avoided. Hence a very stable, precise metal mirror can be produced.

According to the invention, the use of the metal mirror in a reflecting telescope (TMA: three-mirror-anastigmatic telescope, RC: Ritchey-Chretien telescope inter alia) or in an EUV beam source as collector mirror is also included.

The following FIGURE and the following example are intended to describe the subject according to the invention in more detail without restricting the invention to this variant.

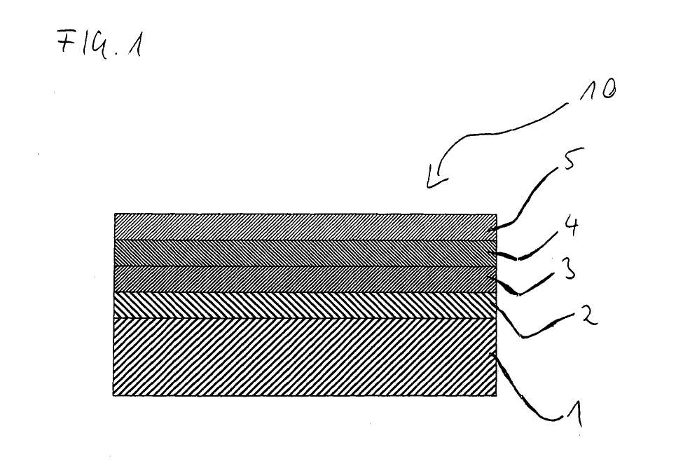

FIG. 1 shows a possible layer construction of the metal mirror according to the invention.

In FIG. 1 an embodiment of the metal mirror 10 according to the invention is represented. An intermediate layer 2 which serves as adhesive- or barrier layer is deposited on the substrate 1 made of AlSiₓₓ bulk material. A polished layer 3 is disposed on this intermediate layer 2. In addition, the metal mirror 10 according to the invention also has a coating layer 4 which is situated between the protective layer 5 and the polished layer 3.

### EXAMPLE

A silicon layer is deposited by means of magnetron sputtering, emanating from a crystalline silicon target. For this purpose, possibly adhesive layers or barrier layers are required depending upon the type of mirror carrier (or substrate) to be coated in order thus to achieve better adhesion or to avoid interdiffusion. These layers are also applied by means of magnetron sputtering (reactively). Both metal oxides and metals can thereby be used. The coating temperature is dependent upon the layer thicknesses to be deposited. The adhesive layers or barrier layers have a layer thickness below 100 nm, for which reason the coating temperature does not increase above 40° C. During the deposition of the polishable silicon layer (>3 μm), the coating temperature can increase to up to 150° C. The layer deposition is implemented in a pressure range of 8·10⁻⁴ mbar to 5·10⁻³ mbar. Argon is used as sputtering gas. If oxides are deposited, a mixture of argon and oxygen is used as sputtering gas. The basic pressure which should be below 5·10⁻⁷ mbar is crucial for these layers.

1. A substrate comprising an aluminium-silicon alloy or crystalline silicon and a polishable layer, which layer consists of amorphous silicon, microcrystalline silicon, silicon carbide, silicon nitride, titanium nitride, aluminium oxide, zirconium oxide, chromium and/or mixtures thereof.

2. The substrate according to claim 1,
wherein an intermediate layer which acts as adhesive or as barrier layer is disposed between the substrate and the polishable layer.

3. The substrate according to claim 1,
wherein the polishable layer has a thickness of 1 μm to 10 μm.

4. The substrate according to claim 2,
wherein the thickness of the intermediate layer which optionally comprises a plurality of layers is between 20 and 200 nm.

5. The substrate according to claim 2,
wherein the intermediate layer comprises a metal oxide or metal.

6. The substrate according to claim 1,
wherein the silicon content of the aluminium-silicon alloy is between 25 and 90% by weight relative to the total mass of the aluminium-silicon alloy.

7. A metal mirror comprising the substrate according to claim 1, the polishable layer being polished to optical quality.

8. The metal mirror according to claim 8,
wherein at least one coating layer is disposed on the surface of the polished layer orientated away from the substrate.

9. The metal mirror according to claim 8,
wherein the at least one coating layer is a metallic layer.

10. The metal mirror according to claim 8,
wherein the at least one coating layer is a dielectric layer or a metal-dielectric layer.

11. The metal mirror according to claim 8,
wherein a further layer is disposed on the coating layer.

12. The metal mirror according to claim 11,
wherein the further layer is a protective layer made of a metal oxide.

13. A method for the production of a metal mirror comprising applying an intermediate layer, a polishable layer, a coating layer, and/or a protective layer to a substrate,
wherein the intermediate layer, the polishable layer, the coating layer and/or the protective layer are applied by a chemical vapour deposition, an atomic layer deposition, an electron beam evaporation and/or a sputtering process.

14. The method for the production of metal mirror according to claim 13,
wherein the sputtering process is carried out with a sputtering gas selected from the group consisting of argon, oxygen, xenon and mixtures thereof.

15. The method for the production of metal mirror according to claim 13,
wherein the silicon content of the aluminium-silicon alloy and the thickness and the materials of the polishable layer are such that extensive deformations due to temperature change are avoided during the production.

16. (canceled)

17. A reflecting telescope or EUV beam source utilizing the metal mirror of claim 7 as a collector mirror.

18. A reflecting telescope or EUV beam source utilizing the metal mirror produced according to claim 13 as a collector mirror.

19. The substrate according to claim 5, wherein the metal oxide is aluminium oxide or zirconium oxide.

20. The substrate according to claim 5, wherein the metal is titanium or chromium.

21. The substrate according to claim 6, wherein the silicon content of the aluminium-silicon alloy is between 40 and 80% by weight relative to the total mass of the aluminium-silicon alloy
